(19) United States
(12) Patent Application Publication
(10) Pub. No.: US 2026/0206293 A1
(43) Pub. Date: Jul. 16, 2026

(54) SILICON CARBIDE SEMICONDUCTOR DEVICE AND POWER CONVERSION APPARATUS

(71) Applicant: Mitsubishi Electric Corporation, Tokyo (JP)

(72) Inventors: Hideyuki HATTA, Tokyo (JP); Kazuya ISHIBASHI, Tokyo (JP)

(73) Assignee: Mitsubishi Electric Corporation, Tokyo (JP)

(21) Appl. No.: 19/417,696

(22) Filed: Dec. 12, 2025

(30) Foreign Application Priority Data
Jan. 16, 2025 (JP) 2025-006069

(51) Int. Cl. H10D 84/00; H10D 8/60; H10D 30/66; H10D 62/53; H10D 62/832; H10D 62/10

(52) U.S. Cl. CPC H10D 84/146; H10D 8/60; H10D 30/665; H10D 62/53; H10D 62/8325; H10D 62/103

(57) ABSTRACT

An object is to provide a technique capable of suppressing a bipolar priority operation at a boundary region. A silicon carbide semiconductor device includes: a semiconductor layer made of silicon carbide where an active region, an outer surrounding region, and a boundary region are defined; and a source electrode provided to an upper side of the semiconductor layer. The semiconductor layer includes a drift layer of a first conductivity type and a well layer of a second conductivity type. The drift layer in the boundary region includes a high point defect density layer overlapped with at least a part of the well layer in a plan view and provided below the well layer to be away from the well layer in a cross-sectional view.

### BACKGROUND

### Technical Field

The present disclosure relates to a silicon carbide semiconductor device and a power conversion apparatus.

### Description of the Background Art

Proposed as a silicon carbide semiconductor device is a technique of providing a Schottky barrier diode (SBD) as a unipolar diode in a unit cell of a metal oxide semiconductor field effect transistor (MOSFET) (for example, Japanese Patent Application Laid-Open No. 2003-017701).

### SUMMARY

Regardless of whether a power conduction region in a reflux operation is an SBD region or a channel region of a MOSFET, a boundary region between the active region and an outer surrounding region includes a position where a unipolar diode cannot be densely disposed but a parasitic pn diode is located for convenience of structure. Thus, a bipolar priority operation in which bipolar current flows preferentially to the parasitic pn diode in the boundary region is performed, and as a result, heat generation due to current concentration occurs in some cases, for example.

The present disclosure therefore has been made to solve the above problems, and it is an object to provide a technique capable of suppressing a bipolar priority operation at a boundary region.

A silicon carbide semiconductor device according to the present disclosure includes: a semiconductor layer made of silicon carbide where an active region in which main current flows, an outer surrounding region surrounding the active region, and a boundary region between the active region and the outer surrounding region are defined; and a source electrode provided to an upper side of the semiconductor layer, wherein the semiconductor layer includes: a drift layer of a first conductivity type; and a well layer of a second conductivity type provided on the drift layer in the boundary region and connected to the source electrode, the drift layer in the boundary region includes a high point defect density layer overlapped with at least a part of the well layer in a plan view and provided below the well layer to be away from the well layer in a cross-sectional view, and a point defect density of the high point defect density layer is higher than a point defect density of the drift layer other than the high point defect density layer.

A bipolar priority operation can be suppressed at a boundary region.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a schematic plan view illustrating a configuration of a silicon carbide semiconductor device according to an embodiment 1.

FIG. 2 is a schematic cross-sectional view illustrating a configuration of the silicon carbide semiconductor device according to the embodiment 1.

FIG. 3 is a schematic cross-sectional view illustrating a configuration of the silicon carbide semiconductor device according to the embodiment 1.

FIG. 4 is a schematic plan view illustrating a configuration of the silicon carbide semiconductor device according to the embodiment 1.

FIG. 5 is a schematic cross-sectional view illustrating a configuration of the silicon carbide semiconductor device according to the embodiment 1.

FIG. 6 is a schematic cross-sectional view illustrating a configuration of the silicon carbide semiconductor device according to the embodiment 1.

FIG. 7 is a schematic cross-sectional view illustrating a configuration of a silicon carbide semiconductor device according to an embodiment 2.

FIG. 8 is a schematic cross-sectional view illustrating a configuration of the silicon carbide semiconductor device according to the embodiment 2.

FIG. 9 is a schematic cross-sectional view illustrating a configuration of a silicon carbide semiconductor device according to an embodiment 3.

FIG. 10 is a schematic cross-sectional view illustrating a configuration of a silicon carbide semiconductor device according to an embodiment 4.

FIG. 11 is a schematic cross-sectional view illustrating a configuration of a silicon carbide semiconductor device according to an embodiment 5.

FIG. 12 is a block diagram illustrating a configuration of a power conversion system to which a power conversion apparatus according to an embodiment 6 is applied.

### DESCRIPTION OF THE PREFERRED EMBODIMENTS

Embodiments are described with reference to the appended diagrams hereinafter. Features described in each embodiment described below is exemplification, thus all features are not necessarily applied. The same or similar reference numerals will be assigned to similar constituent elements in a plurality of embodiments in the description hereinafter, and the different constituent elements are mainly described hereinafter. A specific position and direction such as “upper”, “lower”, “left”, “right”, “front”, or “back”, for example, in the description hereinafter may not necessarily coincide with a position and direction in an actual implementation. Also, when mentioning a certain part having a higher concentration than another part, this refers, for example, to an average concentration or a peak of a certain part being higher than an average concentration or a peak of another part. In contrast, when mentioning a certain part having a lower concentration than another part, this refers, for example, to an average concentration or a peak of a certain part being lower than an average concentration or a peak of another part. Although a first conductivity type is an n type and a second conductivity type is a p type in the description hereinafter, it is also applicable that the first conductivity type is a p type and the second conductivity type is an n type.

### Related technique

Well known is a problem in reliability that when forward current, that is to say, bipolar current continuously flows in a pn diode made up using silicon carbide, a stacking fault occurs in a crystal of silicon carbide and the forward voltage is shifted. This is considered to be caused because minority carriers implanted through the pn diode are recombined with major carriers to cause recombination energy, and the recombination energy enlarges the stacking fault as a plane defect from a base bottom surface dislocation of a silicon carbide substrate as an origination. That is to say, it is considered that the stacking fault blocks flow of current and increases the forward voltage.

Such a shift of the forward voltage also occurs similarly in a switching element such as a transistor made of silicon carbide. The shift of the forward voltage also occurs in a metal oxide semiconductor field effect transistor (MOSFET) using silicon carbide as a type of such a switching element, that is to say, an SiC-MOSFET, for example. The shift of the forward voltage occurs because the MOSFET itself is a unipolar transistor, but includes a bipolar parasitic pn diode as a body diode between a source and a drain. As a result, when bipolar current flows in the body diode of the MOSFET, deterioration of reliability occurs in the manner similar to the pn diode.

Generally, a Schottky barrier diode (SBD) chip having low forward voltage is used for a reflux diode (freewheeling diode) of a switching circuit, and the SBD chip is parallelly connected to a MOSFET chip provided separately from the SBD chip. However, even when the SBD chip and the MOSFET chip are separately provided, deterioration of characteristics of the MOSFET described above occurs as long as the body diode of the SiC-MOSFET functions as the reflux diode.

In the meanwhile, when the unipolar transistor such as the MOSFET includes the built-in unipolar diode as the reflux diode, the body diode functioning as the reflux diode can be suppressed. Proposed as an example of the configuration is a configuration including a built-in SBD as the unipolar diode in a unit cell of the MOSFET. In such a configuration, an n-type drift layer partially exposed from a p-type well layer in a lower part of a source electrode in an active region has contact with a Schottky electrode; thus, an SBD region functioning as the SBD is achieved.

In the unipolar transistor including a built-in unipolar diode in an active region such as a unit cell, for example, diffusion potential of the unipolar diode, that is to say, voltage at which a power conduction operation is started can be designed to be lower than a case of a pn junction. Thus, the bipolar current flowing in the body diode can be suppressed in actual use, and deterioration of characteristics of the active region can be suppressed.

However, when the unipolar current of the built-in SBD increases and potential around the SBD exceeds pn junction potential of the body diode, the body diode is turned on and the bipolar current flows. Thus, there is a limitation on maximum unipolar current which can be flowed in the MOSFET with the built-in SBD. A current density needs to be increased as much as possible to increase a maximum unipolar current density which can be flowed in a chip to reduce a chip cost under such a limitation on the maximum unipolar current.

Considered as a method of increasing the maximum unipolar current density of the MOSFET with the built-in SBD is a method of forming a recombination layer having a high point defect density in a lower part of a body region (a well layer) in the active region by implanting hydrogen or helium, for example. According to such a structure, a positive hole implanted from the body region (the well layer) is easily recombined with electrons, and a positive hole concentration accumulated immediately below the body region (the well layer) is lowered. Thus, the bipolar current hardly flows, and the maximum unipolar current density can be increased.

There is a position where the unipolar diode cannot be densely provided in a boundary region between the active region and the outer surrounding region for convenience of structure (layout). Thus, a parasitic pn diode is formed in some cases around the position where the unipolar diode cannot be densely provided in the boundary region even in the unipolar transistor including a built-in unipolar diode in the active region.

For example, there is generally a region where the SBD region is not partially provided, that is to say, a region having a smaller area ratio (an area density) of the SBD region than the active region for convenience of structure such as routing of the gate electrode to the gate wiring in the boundary region near the gate pad. The boundary region generally includes a position where at least a part of the drift layer has contact with the well region from a viewpoint of holding withstand voltage, and includes a position where the parasitic pn diode is located in the manner similar to the active region. As a result, there is a case in the MOSFET with the built-in SBD where a bipolar priority operation in which the bipolar current preferentially flows is performed more easily in the boundary region than in the active region.

When the bipolar priority operation is performed in the boundary region in a case where large current flows in the chip, a partial heat generation amount increases by a current concentration at the boundary region, and there is concern that deterioration of characteristics occurs by heat according to circumstances. When there is an origination such as a base bottom surface dislocation in a position having a large bipolar current density beyond a scope of assumption, for example, a stacking fault is expanded. Thus, leakage current occurs when a transistor is in an OFF state, and withstand voltage of the transistor is deteriorated in some cases.

When the MOSFET with the built-in SBD in which the unipolar current substantially flows partially includes a position where the bipolar current has lower resistance than the unipolar current, a current concentration easily occurs in the position. Thus, the current concentration in the boundary region occurs in the MOSFET with the built-in SBD more easily than in the MOSFET which does not include the built-in SBD.

As described above, in the MOSFET with the built-in SBD, the recombination layer having the high point defect density is provided in the lower part of the body region (the well layer) in the active region to increase the maximum unipolar current density of the active region in some cases. In this case, since a difference between the maximum unipolar current density of the active region and the maximum unipolar current density of the boundary region increases, there is a problem that the bipolar priority operation is performed more easily in the boundary region.

The unipolar reflux current flows in the channel region of the MOSFET in the reflux operation in the configuration that the channel region of the MOSFET is formed by the second conductivity type region having the small thickness on the first conductivity type region. According to such a configuration, conduction of the bipolar current to the parasitic pn diode (the body diode) can be suppressed between the source and the drain. However, even in such a configuration, there is a position where the unipolar diode cannot be densely provided in the boundary region for convenience of structure in the manner similar to the above MOSFET with the built-in SBD in the active region. Thus, the problem that the bipolar priority operation is performed in the boundary region cannot still be solved.

In contrast, as described hereinafter, according to a silicon carbide semiconductor device of the present embodiment 1, the bipolar priority operation in the boundary region can be suppressed.

### Embodiment 1

Described mainly hereinafter is an example that the silicon carbide semiconductor device according to the present embodiment 1 is an n-channel silicon carbide MOSFET and is a silicon carbide MOSFET including a Schottky barrier diode (SBD), that is to say, an SiC-MOSFET with a built-in SBD. The silicon carbide semiconductor device according to the present embodiment 1 is not limited thereto, but may be an insulated gate bipolar transistor (IGBT) or a reverse conducting IGBT (RC-IGBT). The silicon carbide semiconductor device can achieve a stable operation under high temperature and high voltage and increase of a switch speed more than a normal semiconductor device made of silicon.

Described hereinafter is increase and decrease of potential in a case where a first conductivity type is an n type and a second conductivity type is a p type. Thus, increase and decrease of potential in a case where a first conductivity type is a p type and a second conductivity type is an n type are opposite of the description hereinafter.

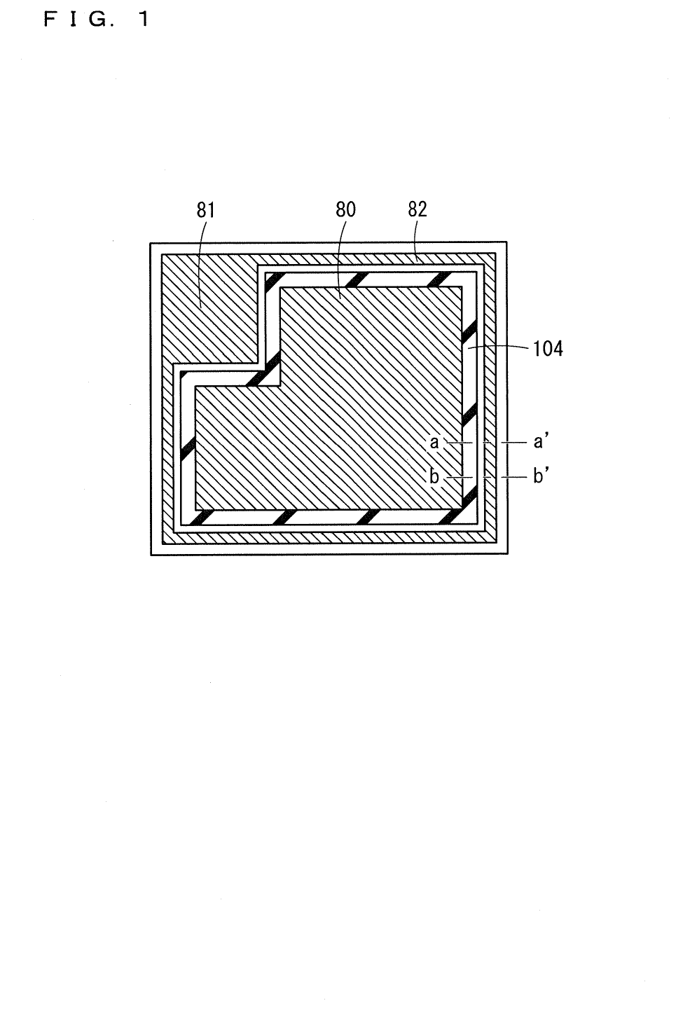

FIG. 1 is a schematic plan view of a configuration of a silicon carbide semiconductor device according to the present embodiment 1 seen from an upper surface. In FIG. 1, provided to a part of an upper surface of an SiC-MOSFET are a gate pad 81, a source electrode 80 located adjacent to the gate pad 81, and a gate wiring 82 connected to the gate pad 81 and surrounding the source electrode 80. FIG. 1 illustrates a high point defect density layer 104, which is described hereinafter.

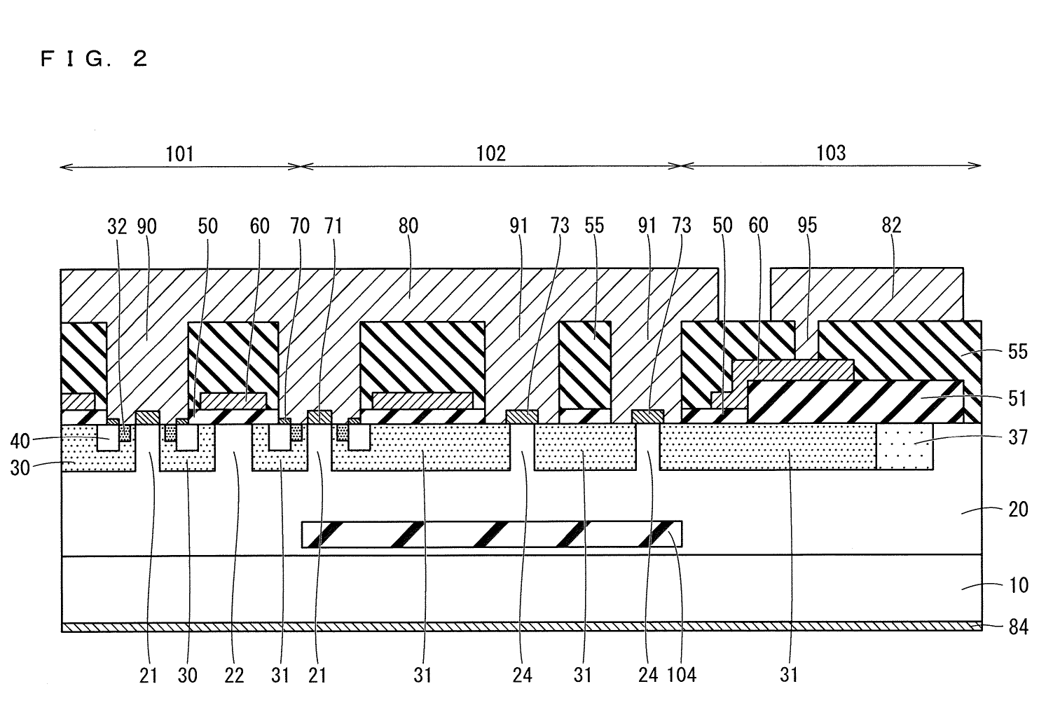

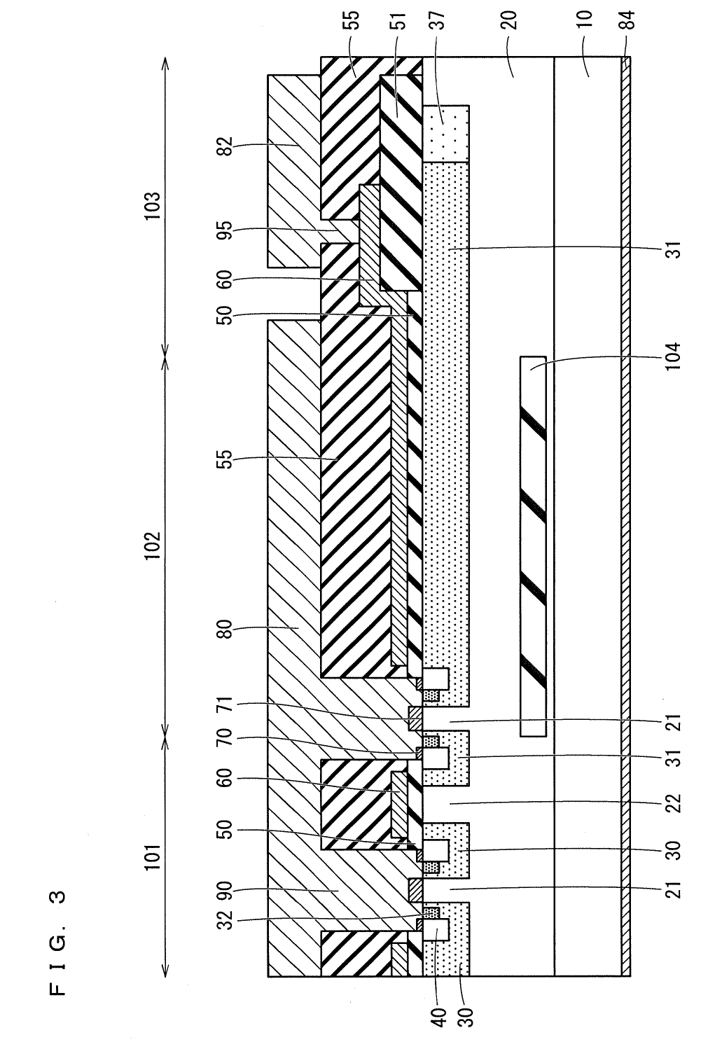

FIG. 2 and FIG. 3 are schematic cross-sectional views each illustrating a configuration of the silicon carbide semiconductor device according to the present embodiment 1. FIG. 2 is a schematic cross-sectional view along an a-a’ line across the source electrode 80 and the gate wiring 82 in FIG. 1, and is a schematic cross-sectional view of a part where a boundary region 102 does not include a routing of the gate electrode 60 from an active region 101 to an outer surrounding region 103. FIG. 3 is a schematic cross-sectional view along a b-b’ line across the source electrode 80 and the gate wiring 82 in FIG. 1, and is a schematic cross-sectional view of a part where the boundary region 102 includes a routing of the gate electrode 60 from the active region 101 to the outer surrounding region 103.

The silicon carbide semiconductor device according to the present embodiment 1 includes a semiconductor layer including a drift layer 20, for example, and made of silicon carbide. The semiconductor layer is provided on a semiconductor substrate 10 in the examples in FIG. 2 and FIG. 3, but may include the semiconductor substrate 10. The active region 101, the boundary region 102, and the outer surrounding region 103 are defined in the semiconductor layer. Herein, an outline of each region is described, and details of each region are described hereinafter.

The active region 101 is a region in which main current flows, and unit cells are arranged at intervals. The active region 101 may include a MOSFET region in which main current flows and an SBD region in which reflux current flows as unit cells, or may also include a MOSFET region in which main current flows and electrical power is conducted in a reverse direction in a reflux operation as an unit cell.

The outer surrounding region 103 is a region surrounding the active region 101, and is located on an end of the silicon carbide semiconductor device. The outer surrounding region 103 may include an electrical field reduction layer such as a junction termination extension (JTE).

The boundary region 102 is a region between the active region 101 and the outer surrounding region 103, and connects the active region 101 and the outer surrounding region 103.

### Active region 101

A configuration of the active region 101 is described next. The semiconductor layer of the active region 101 according to the present embodiment 1 includes an n-type drift layer 20, a p-type first well layer 30, a p-type contact layer 32, and an n-type first source layer 40.

The drift layer 20 is provided on the n-type semiconductor substrate 10. The first well layer 30 is selectively provided on the drift layer 20. A p-type impurity of the first well layer 30 is aluminum (Al), for example. The first well layer 30 is divided by a first separation region 21 and a second separation region 22 each of which is a part of the drift layer 20 in a cross-sectional view.

The first source layer 40 is provided inside an upper part of the first well layer 30 in a cross-sectional view. An n-type impurity of the first source layer 40 is nitrogen (N), for example. A lower end of the first source layer 40 is located more upward than a lower end of the first well layer 30.

The contact layer 32 is provided in a region sandwiched between the first source layer 40 and the first separation region 21 to be separated from the first separation region 21 in an upper part of the first well layer 30 in a cross-sectional view. A p-type impurity of a contact layer 32 is aluminum (Al), for example, and has a higher concentration than a p-type impurity of the first well layer 30.

The gate insulating film 50 made of silicon oxide, for example, is provided over the second separation region 22, the first well layer 30, and a part of the first source layer 40. Provided on the gate insulating film 50 is the gate electrode 60 facing the second separation region 22, the first well layer 30, and an end part of the first source layer 40 via the gate insulating film 50. A region in the first well layer 30 sandwiched between the second separation region 22 and the first source layer 40 and facing the gate electrode 60 via the gate insulating film 50 is referred to as a channel region. An inversion layer is formed in the channel region in an ON operation.

An interlayer insulating film 55 covering the gate electrode 60 and made of silicon oxide is provided on the gate insulating film 50. An ohmic electrode 70 for reducing contact resistance with silicon carbide is provided to a part of an upper surface of the first source layer which is not covered by the gate insulating film 50 and a part of an upper surface of the contact layer 32 having contact with the first source layer 40. Accordingly, the first well layer 30 has ohmic contact with the source electrode 80 via the contact layer 32 and the ohmic electrode 70, and can easily supply and receive electrons and positive holes to and from the ohmic electrode 70 via the contact layer 32 having low resistance.

A first Schottky electrode 71 is provided on an upper surface of the first separation region 21, and is Schottky connected to the first separation region 21. The first Schottky electrode 71 and the first separation region 21 have contact with each other to form the SBD, and diffusion potential of the SBD is lower than that of the pn junction. The first Schottky electrode 71 is preferably provided on the upper surface of the first separation region 21, but may not be provided.

The source electrode 80 is provided on the ohmic electrode 70, the first Schottky electrode 71, and the interlayer insulating film 55. The source electrode 80 is connected to the ohmic electrode 70 and the first Schottky electrode 71 via the first contact hole 90 provided to the gate insulating film 50 and the interlayer insulating film 55, and electrically short-circuits the ohmic electrode 70 and the first Schottky electrode 71. Accordingly, the ohmic electrode 70 and the first Schottky electrode 71 are electrically connected to each other.

The source electrode 80 is provided to an upper side of the semiconductor layer not only in the active region 101 but also in the boundary region 102. The drain electrode 84 is provided to a lower side of the semiconductor substrate 10 not only in the active region 101 but also in the boundary region 102 and the outer surrounding region 103.

### Outer surrounding region 103

A configuration of the outer surrounding region 103 is described next. The semiconductor layer in the outer surrounding region 103 according to the present embodiment1 includes the n-type drift layer 20, a p-type second well layer 31, and a p-type JTE layer 37.

The drift layer 20 is provided on the n-type semiconductor substrate 10. The second well layer 31 is selectively provided on the drift layer 20. A p-type impurity of the second well layer 31 is aluminum (Al), for example.

As illustrated in FIG. 3, the gate electrode 60 is provided to range from the active region 101 to the outer surrounding region 103 through the boundary region 102, and is provided on the second well layer 31 via the gate insulating film 50 and the field insulating film 51. The interlayer insulating film 55 is provided on the gate electrode 60, and a gate contact hole 95 exposing a part of the gate electrode 60 on the field insulating film 51 is provided to the interlayer insulating film 55. The gate wiring 82 provided on the interlayer insulating film 55 is connected to a part of the gate electrode 60 via the gate contact hole 95.

The outer surrounding region 103 includes not only the gate wiring 82 but also the gate pad 81 in FIG. 1. It is preferable that the second well layer 31 be arranged to block high voltage applied from the drain electrode 84 to the field insulating film 51 provided below the gate wiring 82 having potential significantly lower than the drain voltage, thereby suppressing the application of the high voltage. In order to achieve this configuration, in the present embodiment 1, as illustrated in FIG. 2 and FIG. 3, the gate wiring 82 is overlapped with the second well layer 31 in a plan view, and although not shown in the diagrams, the gate pad 81 is also overlapped with the second well layer 31 in a plan view. The JTE layer 37 connected to the second well layer 31 is provided to an outer surrounding side of the second well layer 31, and a p-type impurity of the JTE layer 37 has a concentration lower than a p-type impurity of the second well layer 31.

The second well layer 31 described hereinafter in the boundary region 102 is connected to the source electrode 80 via a second contact hole 91 in FIG. 2 provided to the gate insulating film 50 and the interlayer insulating film 55. Although the gate electrode 60 in FIG. 3 is provided to range from the active region 101 to the outer surrounding region 103, the gate electrode 60 in FIG. 2 is removed at a position where the second contact hole 91 is opened to prevent contact with the source electrode 80.

### Boundary region 102

A configuration of the boundary region 102 is described next. A boundary between the boundary region 102 and the active region 101 is defined by whether or not main current flows, for example. A boundary between the boundary region 102 and the outer surrounding region 103 is defined by whether or not the source electrode 80 is connected to the semiconductor layer, for example.

The semiconductor layer of the boundary region 102 according to the present embodiment 1 includes the n-type drift layer 20, the p-type second well layer 31 as the well layer, and impurity layers similar to the p-type contact layer 32 and the n-type first source layer 40.

The drift layer 20 is provided on the n-type semiconductor substrate 10. The second well layer 31 is selectively provided on the drift layer 20 in the manner similar to the outer surrounding region 103. The second well layer 31 is ohmic connected to the source electrode 80. The second well layer 31 is divided by a third separation region 24 as a part of the drift layer 20 in a cross-sectional view.

A second Schottky electrode 73 is provided to an upper surface of the third separation region 24. Since the second Schottky electrode 73 is Schottky connected to the source electrode 80, a Schottky contact in which unipolar current flows in the reflux operation is provided, and an SBD is provided.

The configurations of the active region 101, the boundary region 102, and the outer surrounding region 103 are not limited thereto described above. For example, it is also applicable that the gate electrode 60 is not provided to the outer surrounding region 103 and the second well layer 31 and the JTE layer 37 are not provided to the outer surrounding region 103.

The gate electrode 60 is routed to connect the active region 101 and the outer surrounding region 103 in the boundary region 102 in FIG. 3. In such a configuration, there is a position where a Schottky contact, that is to say, an SBD cannot be provided. Thus, there is a position in the boundary region 102 having a smaller SBD area density than the active region 101 for convenience of structure.

Since a unipolar current density which can be flowed around a region having a small SBD area density is small, the bipolar current preferentially flows in this region when large reflux current flows in the MOSFET chip with the built-in SBD. The area of the region where the bipolar current preferentially flows in the boundary region 102 is smaller than the whole area of the active region 101, and the bipolar current flowing in the boundary region 102 has lower resistance than that flowing in the active region 101.

Thus, the bipolar current density gets high beyond a scope of assumption in the region where the bipolar current preferentially flows in the boundary region 102, and concern about extension of crystal defect and deterioration due to heat occurs. Described above is the case where the area density of the SBD region cannot be increased in the boundary region 102 by routing the gate electrode 60. However, in addition to this case, there is also a case where the area density of the SBD region cannot be increased in the boundary region 102 also by forming the contact layer in the second well layer 31, for example.

### High point defect density layer 104

In order to solve such a problem, in the present embodiment 1, at least a part of the drift layer 20 in the boundary region 102 includes the high point defect density layer 104 as a low lifetime layer as illustrated in FIG. 2 and FIG. 3. The high point defect density layer 104 is overlapped with at least a part of the second well layer 31 in a plan view, and is provided below the second well layer 31 to be away from the second well layer 31 in a cross-sectional view. A point defect density of the high point defect density layer 104 is higher than that of the drift layer 20 other than the high point defect density layer 104.

An example of a method of manufacturing the silicon carbide semiconductor device according to the present embodiment 1 is described briefly herein. Firstly, the semiconductor layer made up of the drift layer 20, for example, is formed by epitaxial growth on the semiconductor substrate 10. Then, the n-type and p-type impurities are selectively ion-implanted into the semiconductor layer using a patterning mask to form the first well layer 30, the second well layer 31, the contact layer 32, and the first source layer 40.

Next, hydrogen (H) or helium (He), for example, is selectively ion-implanted into at least a part of the drift layer 20 in the boundary region 102 using the patterning mask. Then, when thermal processing is performed at high temperature, hydrogen or helium is thermally diffused, and the high point defect density layer 104 is formed in a position where hydrogen or helium is implanted. After the thermal processing, the various insulating films and the various electrodes are formed, and the silicon carbide semiconductor device according to the present embodiment 1 is completed.

According to such a silicon carbide semiconductor device, the positive holes flowing from the second well layer 31 and the electrons flowing from the semiconductor substrate 10 are easily recombined in the high point defect density layer 104 when the parasitic pn diode is operated; thus, the positive holes hardly flow to a side of the semiconductor substrate 10. As a result, the bipolar current hardly flows in the high point defect density layer 104 and around the high point defect density layer 104, and the bipolar priority operation is suppressed. Thus, deterioration due to the current concentration at the boundary region 102 and deterioration of characteristics due to the expansion of the stacking fault can be suppressed, for example.

The pn diode in which the bipolar priority operation is performed is formed from a region ohmic connected to the source electrode 80 via the contact layer 32, for example, between the second well layer 31 and the drift layer 20. Thus, the high point defect density layer 104 is preferably overlapped with at least a part of the contact layer 32 in a plan view. However, the high point defect density layer 104 may be narrowed or may not be provided in a region in which sufficient unipolar current can be flowed such as a region adjacent to a region in which SBDs are disposed at a high density in a plan view.

The pn diode made up of the second well layer 31 and the drift layer 20 has higher resistance on a current route as getting away from the contact layer 32 on the second well layer 31, and tends not to perform the bipolar priority operation. Thus, the high point defect density layer 104 may not be provided to a region away from the contact layer 32. In FIG. 2 and FIG. 3, the high point defect density layer 104 is provided over the whole boundary region 102. However, the high point defect density layer 104 may not be provided to a side of the outer surrounding region 103, but may be provided to only a side of the active region 101.

The contact layer 32 on the second well layer 31 is preferably connected to the source electrode 80 via the ohmic electrode 70 to obtain favorable ohmic connection; however, the configuration is not limited thereto. For example, it is also applicable that the ohmic electrode 70 is omitted and the contact layer 32 is directly ohmic connected to the source electrode 80.

In the example in FIG. 2 and FIG. 3, the third separation region 24 is connected to the source electrode 80 in the second contact hole 91 via the second Schottky electrode 73 in the boundary region 102; thus, the SBD is provided. However, the configuration is not limited thereto. In the configuration that the SBD is provided to the boundary region 102, it is also applicable that the high point defect density layer 104 is not provided immediately below the third separation region 24 in which the SBD is provided to intermittently (discretely) provide the high point defect density layer 104. Accordingly, leakage current in occurrence of high electrical field in a lower end of the second well layer 31 and a lower part of the second Schottky electrode 73, for example, can be reduced.

Ions of hydrogen (H) or helium (He) may be implanted after thermal processing in manufacturing the high point defect density layer 104 according to the present embodiment1. A dose amount of ion implantation is preferably set within a range from 1×10¹²cm⁻² to 1×10¹⁶cm⁻². It is because there is a possibility that when the dose amount is too small, the effect of suppressing the bipolar priority operation described above gets small, and when the dose amount is too large, the semiconductor layer is warped in the ion implantation and such a state may cause negative influence on a subsequent process and element characteristics.

The high point defect density layer 104 is not provided to an uppermost surface of the silicon carbide semiconductor device, thus is not actually seen from a side of the upper surface of the silicon carbide semiconductor device. However, illustrated in a plan view in FIG. 1, for example, is the high point defect density layer 104 to clarify a planar positional relationship. In the example in FIG. 1, the high point defect density layer 104 is provided to the boundary region 102 around the gate pad 81. According to such a configuration, obtained is the effect of suppressing the bipolar priority operation also around the gate pad 81.

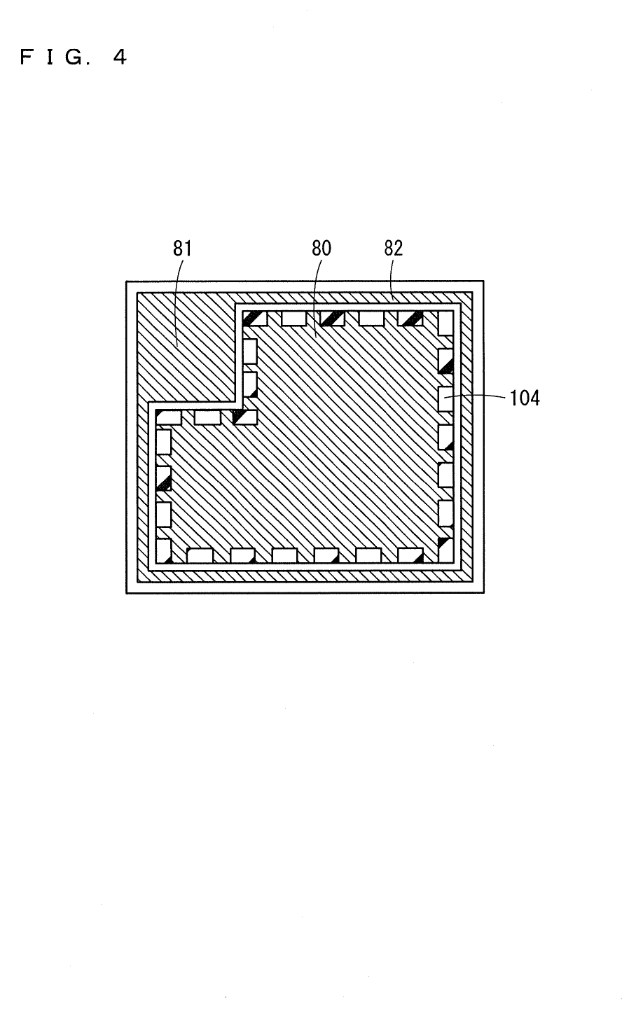

The high point defect density layer 104 may be continuously provided to extend around the active region 101 as illustrated in FIG. 1, or may also be intermittently provided as illustrated in FIG. 4. For example, when there is a process of using a patterning mask intermittently opened in the other implantation process, simplification of the process regarding the patterning can be expected by forming the high point defect density layer 104 using the patterning mask.

In the example in FIG. 2, a distance from the high point defect density layer 104 to the lower end of the drift layer 20, that is to say, a distance from the high point defect density layer 104 to the semiconductor substrate 10 is smaller than a distance from the high point defect density layer 104 to the second well layer 31. According to such a configuration, since the high point defect density layer 104 is provided to the region in which a hole density gets high in power conduction in the SBD, the hole density can be effectively reduced, and the effect of suppressing the bipolar priority operation can be increased.

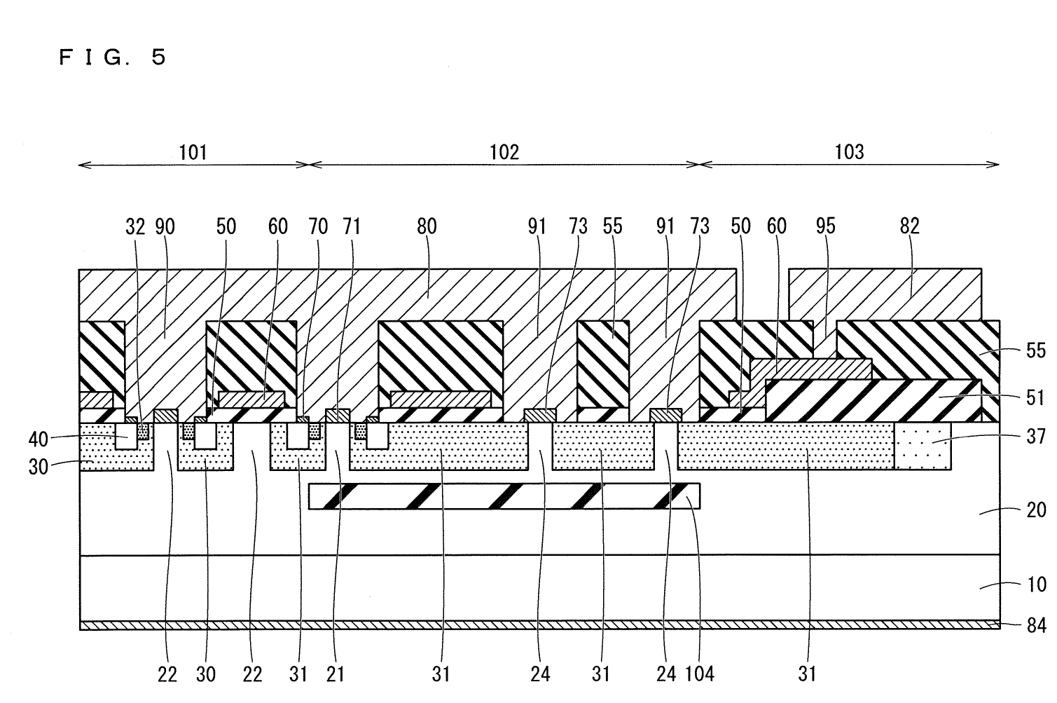

As the example in FIG. 5, the distance from the high point defect density layer 104 to the second well layer 31 may be smaller than the distance from the high point defect density layer 104 to the lower end of the drift layer 20. The bipolar current from the second well layer 31 in the boundary region 102 flows not only in a vertical direction in a cross-sectional view toward the drain electrode 84 along a shortest route but also in a lateral direction in a cross-sectional view as illustrated in FIG. 5 to some extent. Thus, in the configuration that the high point defect density layer 104 is provided near the second well layer 31, the current route of the bipolar current flowing in the lateral direction can be elongated or can have high resistance. Thus, the effect of suppressing the current concentration by the bipolar priority operation at the boundary region 102 can be increased.

When the high point defect density layer 104 has contact with the second well layer 31, leakage current via a point defect in the interface between the second well layer 31 and the drift layer 20 increases, and there is concern of reduction of withstand voltage of the semiconductor element. Thus, such a configuration is not preferable. The inventors have confirmed that the bipolar priority operation in the boundary region 102 cannot be effectively suppressed in the configuration that the high point defect density layer 104 is provided in the third separation region 24. In the present embodiment 1, the high point defect density layer 104 is provided below the second well layer 31 to be away from the second well layer 31 in a cross-sectional view in consideration of the above condition.

In the example in FIG. 2, a width of the high point defect density layer 104 corresponding to a length in the lateral direction in a cross-sectional view is the same as that of the boundary region 102. However, the width of the high point defect density layer 104 may be smaller than that of the boundary region 102 so as to be within the boundary region 102. When the width of the high point defect density layer 104 is too small, the above effect of suppressing the bipolar priority operation is reduced. Thus, the width of the high point defect density layer 104 is preferably set in accordance with the specification of the silicon carbide semiconductor device.

When the contact layer 32 connected to the source electrode 80 via the ohmic contact is located on the second well layer 31 in the boundary region 102, the unipolar current flowing from the SBD of the active region 101, for example, does not reach the boundary region 102, and the bipolar priority operation easily occurs. Thus, the high point defect density layer 104 is preferably overlapped with at least a part of the contact layer 32 and then at least a part of the second well layer 31 in a plan view.

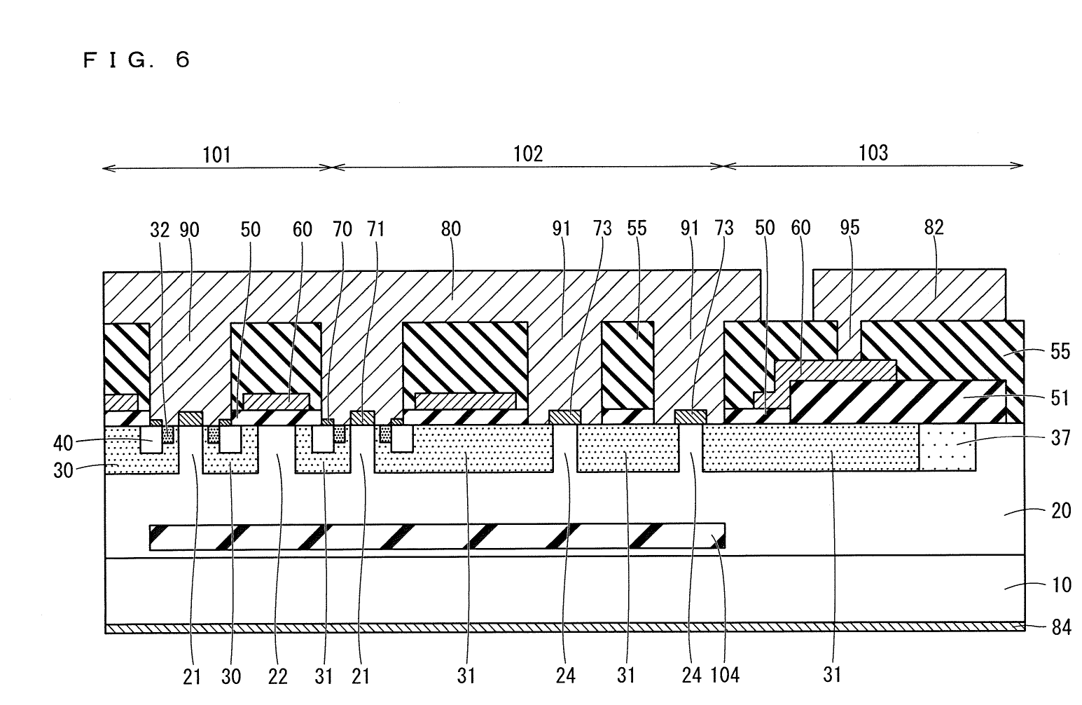

As illustrated in FIG. 6, the high point defect density layer 104 may be provided to a part of the active region 101 beyond the boundary between the boundary region 102 and the active region 101. Then, the high point defect density layer 104 may be overlapped with at least a part of the SBD region in the active region 101 in a plan view. According to such a configuration, a part of the current route of the bipolar current flowing in the lateral direction can be blocked, or the current route can be elongated or have high resistance. Thus, the bipolar priority operation at the active region 101 can be suppressed. However, when the high point defect density layer 104 is provided to the whole active region 101, tendency of performing the bipolar priority operation in the boundary region 102 is increased. Thus, the high point defect density layer 104 is preferably provided to a part of the active region 101.

The point defect density of the drift layer 20 of the active region 101 may be lower than that of the drift layer 20 in the boundary region 102. According to such a configuration, the maximum unipolar current in the boundary region 102 can be increased, and defect due to a current concentration in overcurrent conduction and deterioration of SBD power conduction can be suppressed.

The point defect density of the drift layer 20 in the outer surrounding region 103 may be lower than that of the drift layer 20 in the boundary region 102. According to such a configuration, reduction of withstand voltage of the silicon carbide semiconductor device and increase of leakage current can be suppressed.

Although not illustrated in the diagrams, it is also applicable that the high point defect density layer 104 is provided below the gate pad 81; thus, the point defect density of the drift layer 20 below the gate pad 81 is higher than that of the drift layer 20 of the active region 101. According to such a configuration, the maximum unipolar current below the gate pad 81 can be increased, and defect due to a current concentration in overcurrent conduction and deterioration of SBD power conduction can be suppressed.

### Embodiment 2

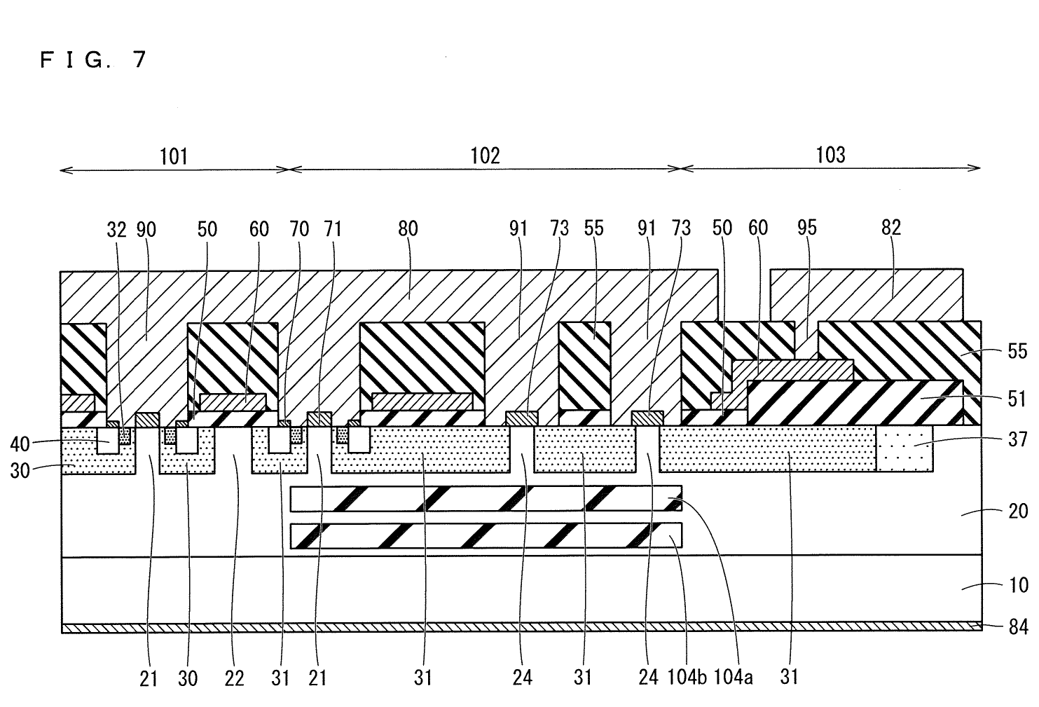

FIG. 7 is a schematic cross-sectional view illustrating a configuration of the silicon carbide semiconductor device according to the present embodiment 2 and is a schematic cross-sectional view corresponding to FIG. 2. In the present embodiment 2, the plurality of high point defect density layers 104 are arranged from the second well layer 31 toward the lower end of the drift layer 20. According to the present embodiment 2 having such a configuration, since the total length (the thickness) of the high point defect density layer 104 gets large in the depth direction in the drift layer 20, the effect of suppressing the bipolar priority operation can be increased more than the embodiment 1.

The effect similar to the above description can be achieved even if one high point defect density layer 104 having a large thickness is formed by ion implantation at multiple stages while implantation energy is gradually changed, for example. However, it is extremely difficult to make concentration peak values (that is to say, peak values of the point defect density) of hydrogen or helium after implantation completely coincide with each other and change only the thicknesses because of characteristics of ion implantation. In contrast, in the present embodiment 2, the plurality of high point defect density layers 104 having different peak values and peak positions can be easily formed.

In the description hereinafter, the high point defect density layer 104 on the side of the second well layer 31 is referred to as a first high point defect density layer 104a, and the high point defect density layer 104 on a side of a lower end of the drift layer 20, that is to say, a side of the semiconductor substrate 10 is referred to as a second high point defect density layer 104b.

The peak values of the point defect density of the first high point defect density layer 104a and the second high point defect density layer 104b may be the same as each other. The peak values thereof may be different from each other by setting the peak value of the point defect density of the second high point defect density layer 104b to be higher than that of the first high point defect density layer 104a. Since the hole density is high in the region near the semiconductor substrate 10 in the reflux operation, the hole density can be effectively reduced in the configuration that the peak value of the point defect density of the second high point defect density layer 104b is high, and the effect of suppressing the bipolar priority operation can be increased.

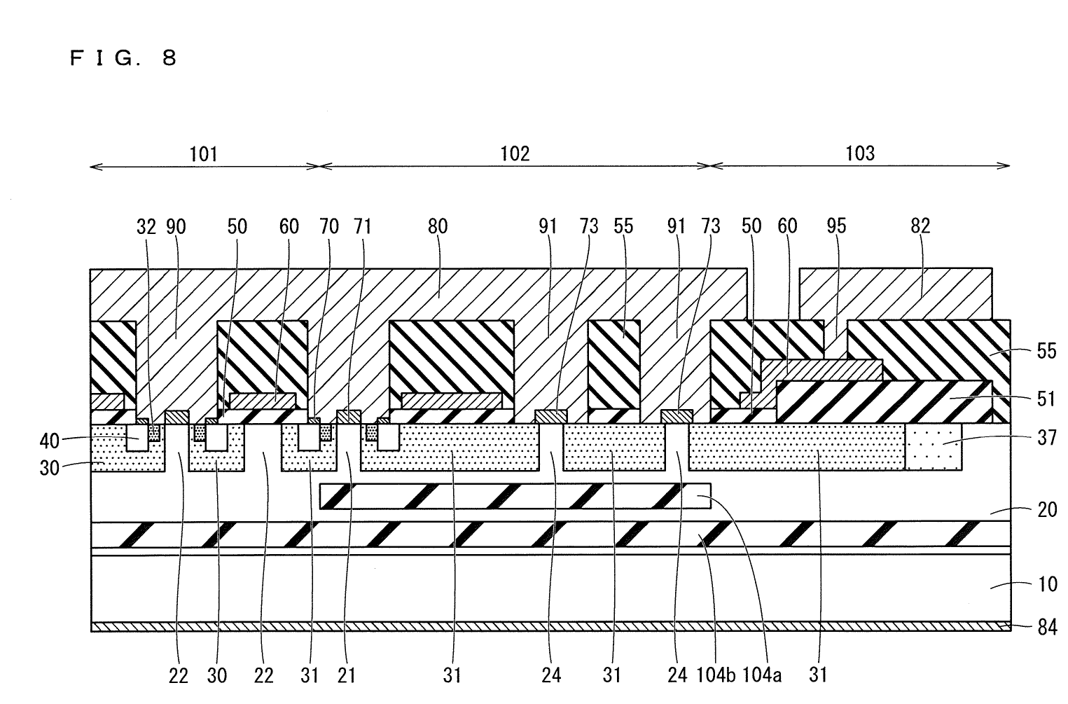

As illustrated in FIG. 8, the second high point defect density layer 104b may be provided to the whole region from the active region 101 to the outer surrounding region 103 while the first high point defect density layer 104a is provided to the boundary region 102. According to such a configuration, the effect of suppressing the bipolar priority operation and the current concentration in the boundary region 102 can be obtained while the unipolar current of the active region 101 is increased in the reflux operation.

The second high point defect density layer 104b is provided to the whole region in the example in FIG. 8, but may be provided to the active region 101 and the boundary region 102 except for the outer surrounding region 103. At least one of the plurality of high point defect density layers 104 may be provided across the boundary between the active region 101 and the boundary region 102. Also according to such a configuration, the effect of suppressing the bipolar priority operation and the current concentration in the boundary region 102 can be obtained while the unipolar current of the active region 101 is increased in the reflux operation. When the second high point defect density layer 104b is provided to the whole region, the process of forming the patterning of the second high point defect density layer 104b can be omitted. Thus, the manufacturing cost can be reduced.

### Embodiment 3

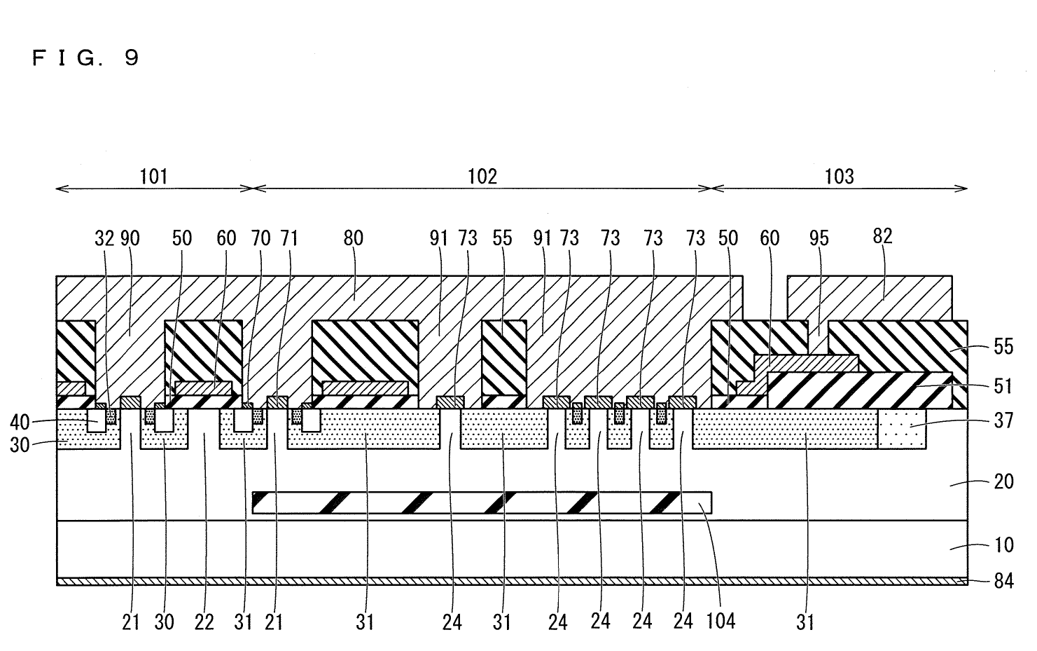

FIG. 9 is a schematic cross-sectional view illustrating a configuration of the silicon carbide semiconductor device according to the present embodiment 3 and is a schematic cross-sectional view corresponding to FIG. 2. In the present embodiment 3, the second Schottky electrode 73 is provided to the upper surface of the third separation region 24 dividing the second well layer 31 in the boundary region 102. The second Schottky electrode 73 is Schottky connected to the source electrode 80; thus, the SBD is provided. Then, the pn diode made up of the second well layer 31 adjacent to the third separation region 24 and the drift layer 20 and the SBD are parallelly connected; thus, a junction barrier Schottky diode (JBS diode) is provided to the boundary region 102.

Since the JBS diode is provided to the boundary region 102, the effect of suppressing the bipolar priority operation around the boundary region 102 is obtained. Furthermore, since the high point defect density layer 104 is provided to the boundary region 102, the effect of suppressing the bipolar priority operation of the boundary region 102 more effectively is obtained.

As illustrated in FIG. 9, it is also applicable that the p-type contact layer 32 having a high concentration is provided to an inner side of the upper surface of the second well layer 31 of the JBS diode; thus, the ohmic contact with the source electrode 80 is provided, or the contact layer 32 is not provided. The unipolar current having a sufficient current density can be flowed in the region around the third separation region 24 in the JBS diode region, and bipolar priority operation hardly occurs. Thus, it is also applicable that the high point defect density layer 104 is not provided immediately below the third separation region 24 constituting the JBS diode but is intermittently provided in the lateral direction in a cross-sectional view as illustrated in FIG. 9.

The JBS diode may be provided in a region in the active region 101 closest to the boundary region 102. The unipolar current flowing from the SBD of the active region 101 also flows in the lateral direction in a cross-sectional view. Thus, when the JBS diode is provided in the active region 101, the effect of suppressing the bipolar priority operation of the boundary region 102 can be obtained.

### Embodiment 4

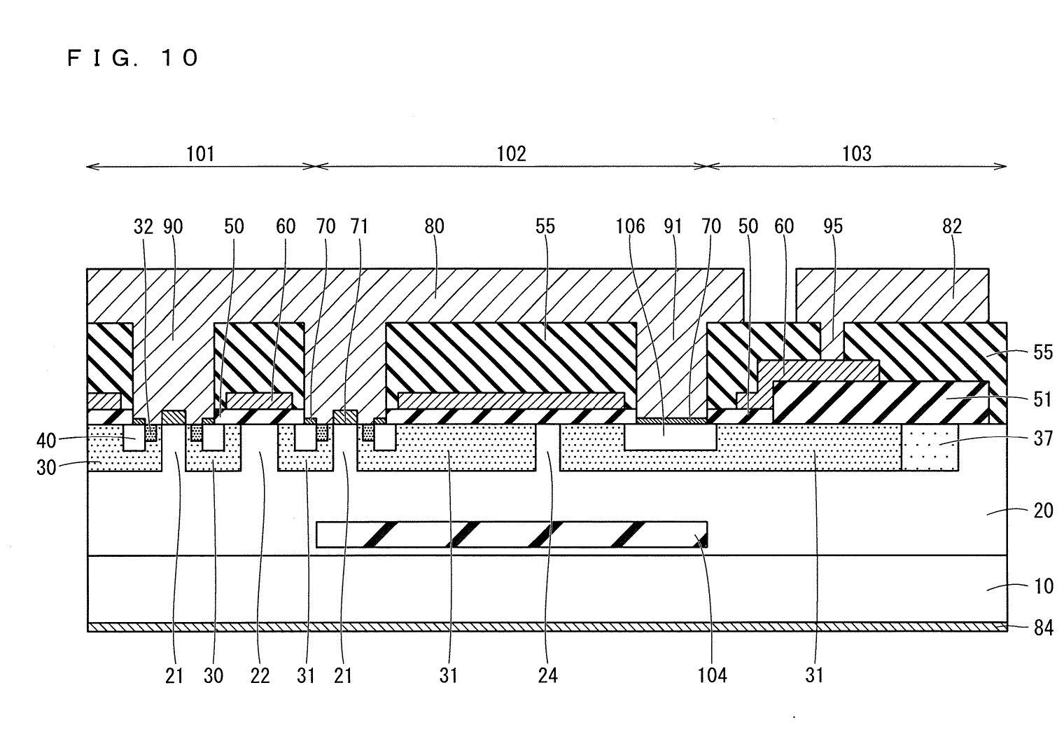

FIG. 10 is a schematic cross-sectional view illustrating a configuration of the silicon carbide semiconductor device according to the present embodiment 4 and is a schematic cross-sectional view corresponding to FIG. 2. In the present embodiment 4, a source contact layer 106 having a high n-type impurity concentration rather than a p-type impurity concentration is provided on the second well layer 31 in the boundary region 102, and the ohmic electrode 70 is provided on the source contact layer 106. Although the p-type contact layer 32 is normally provided to the p-type second well layer 31 to reduce contact resistance, the second well layer 31 is connected to the source electrode 80 via the n-type source contact layer 106 and the ohmic electrode 70 in the present embodiment 4.

According to such a configuration, a forward bias is hardly applied to the pn junction made up of the second well layer 31 and the drift layer 20 in the boundary region 102 in the reflux operation. Thus, the bipolar current passing through the second well layer 31 in the boundary region 102 and the outer surrounding region 103 hardly flows, and the effect of suppressing the bipolar priority operation can be obtained.

The n-type source contact layer 106 is provided to the boundary region 102 in the example in FIG. 10, but may be provided to the outer surrounding region 103 instead of the boundary region 102. In this case, the second well layer 31 is connected to the source electrode 80 via the source contact layer in the outer surrounding region 103.

### Embodiment 5

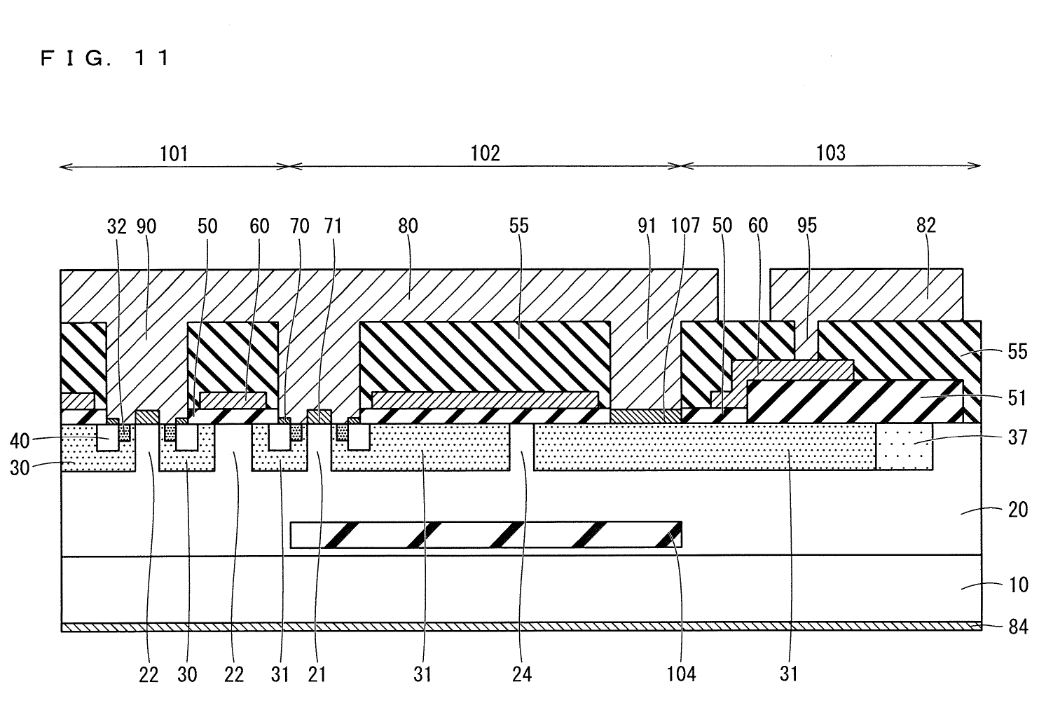

FIG. 11 is a schematic cross-sectional view illustrating a configuration of the silicon carbide semiconductor device according to the present embodiment 5 and is a schematic cross-sectional view corresponding to FIG. 2. In the present embodiment 5, the third Schottky electrode 107 as the Schottky electrode is provided instead of the contact layer 32 having the high p-type impurity concentration on the second well layer 31 in the boundary region 102. The second well layer 31 is connected to the source electrode 80 via the third Schottky electrode 107. Accordingly, the second well layer 31 and the source electrode 80 form the Schottky contact instead of the ohmic contact.

According to such a configuration, a forward bias is hardly applied to the pn junction made up of the second well layer 31 and the drift layer 20 in the boundary region 102 in the reflux operation in the manner similar to the embodiment 4. Thus, the bipolar current passing through the second well layer 31 in the boundary region 102 and the outer surrounding region 103 hardly flows, and the effect of suppressing the bipolar priority operation can be obtained.

Although the third Schottky electrode 107 is provided to the boundary region 102 in the example in FIG. 11, but may be provided to the outer surrounding region 103 instead of the boundary region 102. In this case, the second well layer 31 is connected to the source electrode 80 via the third Schottky electrode 107 in the outer surrounding region 103.

### Embodiment 6

A power conversion apparatus according to the present embodiment 6 includes the silicon carbide semiconductor device according to the embodiments 1 to 5 described above. Although the power conversion apparatus according to the present embodiment 6 is not limited to a specific power conversion apparatus, a case of applying the power conversion apparatus according to the present embodiment 6 to a three-phase inverter is described hereinafter.

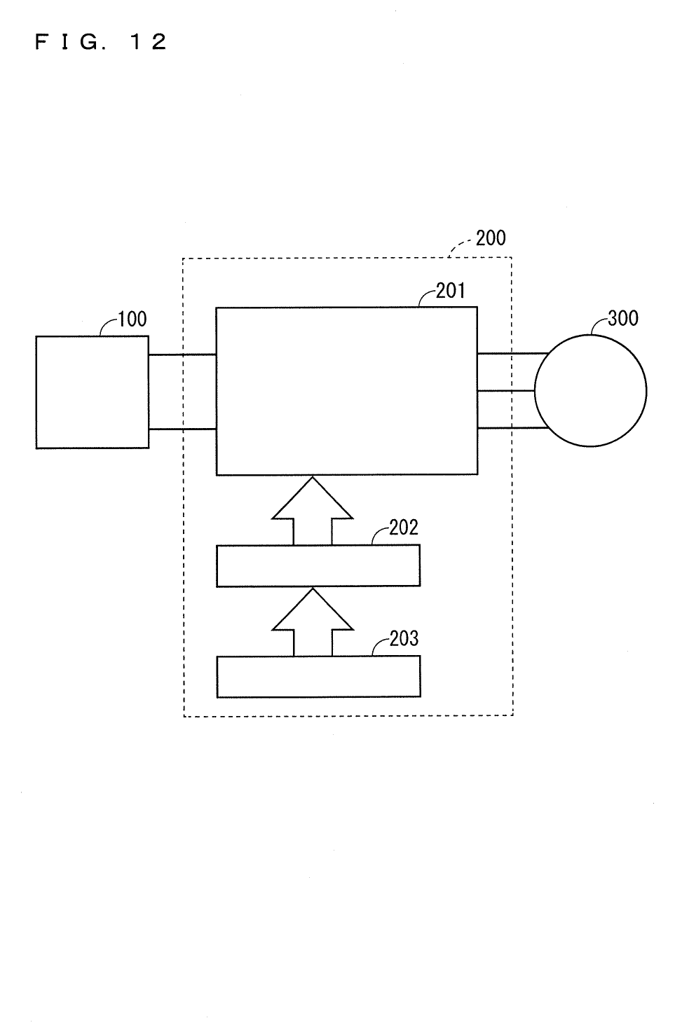

FIG. 12 is a block diagram illustrating a configuration of a power conversion system to which a power conversion apparatus 200 according to the present embodiment 6 is applied. The power conversion system illustrated in FIG. 12 is made up of a power source 100, the power conversion apparatus 200, and a load 300. The power source 100, which is a direct current power source, supplies a direct current power to the power conversion apparatus 200. The power source 100 can be made up of various types of power sources, thus may be made up of a direct-current system, a solar battery, or a storage battery, or may be made up of a rectification circuit connected to an alternating-current system or an AC/DC converter, for example. The power source 100 may also be made up of a DC/DC converter which converts a direct current power outputted from the direct current system into a predetermined electrical power.

The power conversion apparatus 200 is a three-phase inverter connected between the power source 100 and the load 300. The power conversion apparatus 200 converts the direct current power supplied from the power source 100 into the alternating current power, and supplies the alternating current power to the load 300. As illustrated in FIG. 12, the power conversion apparatus 200 includes a main conversion circuit 201 converting the direct current power into the alternating current power and outputting the alternating current power, a drive circuit 202 outputting a drive signal for driving each switching element in the main conversion circuit 201, and a control circuit 203 outputting a control signal for controlling the drive circuit 202 to the drive circuit 202.

The load 300 is a three-phase electrical motor driven by the alternating current power supplied from the power conversion apparatus 200. The load 300 is not for specific purpose of use but is the electrical motor mounted to various types of electrical apparatuses, thus it is used as the electrical motor for a hybrid car, an electrical car, a rail vehicle, an elevator, or an air-conditioning apparatus, for example.

The power conversion apparatus 200 is described in detail hereinafter. The main conversion circuit 201 includes a switching element and a reflux diode (not shown). The reflux diode is built in the switching element. When a switching is performed on the switching element, the main conversion circuit 201 converts the direct current power supplied from the power source 100 into the alternating current power and supplies the alternating current power to the load 300. Various types of configurations are assumed as specific configurations of the main conversion circuit 201. The main conversion circuit 201 according to the present embodiment 6 is a three-phase full-bridge circuit having two levels, and can be made up of six switching elements and six reflux diodes being antiparallel to each of each of the switching elements. The silicon carbide semiconductor device according to any one of the embodiments 1 to 5 described above is applied as the switching element of the main conversion circuit 201. The two switching elements among the six switching elements are series-connected to each other to constitute upper and lower arms, and each of the upper and lower arms constitutes each phase (U-phase, V-phase, and W-phase) of the full-bridge circuit. An output terminal of each of the upper and lower arms, that is to say, three output terminals of the main conversion circuit 201 are connected to the load 300.

The drive circuit 202 generates the drive signal for driving the switching element of the main conversion circuit 201, and supplies the drive signal to a control electrode of the switching element of the main conversion circuit 201. Specifically, the drive circuit 202 outputs the drive signal for switching the switching element to an ON state and the drive signal for switching the switching element to an OFF state to the control electrode of each switching element in accordance with the control signal from the control circuit 203 described hereinafter. The drive signal is a voltage signal (ON signal) larger than a threshold voltage of the switching element when the switching element is kept in the ON state, and the drive signal is a voltage signal (OFF signal) smaller than the threshold voltage of the switching element when the switching element is kept in the OFF state.

The control circuit 203 controls the switching element of the main conversion circuit 201 to supply a desired power to the load 300. Specifically, the control circuit 203 calculates a time when each switching element of the main conversion circuit 201 needs to enter the ON state (ON time), based on the electrical power which needs to be supplied to the load 300. For example, the control circuit 203 calculates the time so that the main conversion circuit 201 can be controlled by pulse width modulation (PWM) control for modulating the ON time of the switching element in accordance with the voltage which needs to be outputted. Then, the control circuit 203 outputs a control instruction (control signal) to the drive circuit 202 so that the ON signal is outputted to the switching element which needs to enter the ON state and the OFF signal is outputted to the switching element which needs to enter the OFF state at each time. The drive circuit 202 outputs the ON signal or the OFF signal as the drive signal to the control electrode of each switching element in accordance with the control signal.

Since the silicon carbide semiconductor device according to the embodiments 1 to 5 is used for the main conversion circuit 201 in the power conversion apparatus according to the present embodiment 6, the power conversion apparatus with low loss and increasing reliability of high-speed switching can be achieved.

Although the example of applying the silicon carbide semiconductor device according to the embodiments 1 to 5 to the three-phase inverter having the two levels is described in the present embodiment 6, the application of the silicon carbide semiconductor device according to the present embodiment 6 is not limited thereto, but can be applied to the various power conversion apparatuses. Although the power conversion apparatus according to the present embodiment 6 is the power conversion apparatus having the two levels, a power conversion apparatus having three or multiple levels may also applied. The power conversion apparatus described above may be applied to a single-phase inverter when the electrical power is supplied to a single-phase load. The power conversion apparatus described above can also be applied to a DC/DC converter or an AC/DC converter when the electrical power is supplied to a direct current load, for example.

The load described above of power conversion apparatus according to the present embodiment 6 is not limited to the electrical motor. The power conversion apparatus can also be used as a power source apparatus of an electrical discharge machine, a laser beam machine, an induction heat cooking device, or a non-contact power feeding system, for example, and can also be further used as a power conditioner of a solar power system or an electricity storage system, for example.

In the above description, the silicon carbide semiconductor device according to each embodiment is the planar silicon carbide semiconductor device, but may also be a trench-type the silicon carbide semiconductor device. For example, in the active region 101 in the configuration in FIG. 1, a stripe gate trench structure in which a transistor is formed and a stripe Schottky structure in which a Schottky electrode is embedded may be alternately provided in parallel to each other.

In the present disclosure in English, articles “a” and “an” indicate one or more matters. Thus, “a”, “an”, “one or more”, and “at least one” can be used in the same sense.

Each embodiment and each modification example can be arbitrarily combined, or each embodiment and each modification can be appropriately varied or omitted.

The aspects of the present disclosure are collectively described hereinafter as appendixes.

### Appendix 1

A silicon carbide semiconductor device, comprising:

a semiconductor layer made of silicon carbide where an active region in which main current flows, an outer surrounding region surrounding the active region, and a boundary region between the active region and the outer surrounding region are regulated; and a source electrode provided to an upper side of the semiconductor layer, wherein

the semiconductor layer includes:

a drift layer of a first conductivity type; and

a well layer of a second conductivity type provided on the drift layer in the boundary region and connected to the source electrode,

the drift layer in the boundary region includes at least one high point defect density layer overlapped with at least a part of the well layer in a plan view and provided below the well layer to be away from the well layer in a cross-sectional view, and

a point defect density of the high point defect density layer is higher than a point defect density of the drift layer other than the high point defect density layer.

### Appendix 2

The silicon carbide semiconductor device according to Appendix 1, wherein

the active region includes a MOSFET region in which the main current flows and an SBD region in which reflux current flows.

### Appendix 3

The silicon carbide semiconductor device according to Appendix 1, wherein

the active region includes a MOSFET region in which the main current flows and electrical power is conducted in a reverse direction in a reflux operation.

### Appendix 4

The silicon carbide semiconductor device according to any one of Appendixes 1 to 3, wherein

a point defect density of the drift layer in the active region is lower than a point defect density of the drift layer in the boundary region.

### Appendix 5

The silicon carbide semiconductor device according to any one of Appendixes 1 to 4, wherein

a point defect density of the drift layer in the outer surrounding region is lower than a point defect density of the drift layer in the boundary region.

### Appendix 6

The silicon carbide semiconductor device according to any one of Appendixes 1 to 5, wherein

a gate pad is provided to the outer surrounding region, and

a point defect density of the drift layer below the gate pad is higher than a point defect density of the drift layer in the active region.

### Appendix 7

The silicon carbide semiconductor device according to any one of Appendixes 1 to 6, wherein

a distance from the high point defect density layer to the well layer is smaller than a distance from the high point defect density layer to a lower end of the drift layer.

### Appendix 8

The silicon carbide semiconductor device according to any one of Appendixes 1 to 6, wherein

a distance from the high point defect density layer to the lower end of the drift

layer is smaller than a distance from the high point defect density layer to the well layer.

### Appendix 9

The silicon carbide semiconductor device according to any one of Appendixes 1 to 6, wherein

the plurality of high point defect density layers are arranged from the well layer toward the lower end of the drift layer.

### Appendix 10

The silicon carbide semiconductor device according to Appendix 9, wherein

at least one of the plurality of high point defect density layers is provided across a boundary between the active region and the boundary region.

### Appendix 11

The silicon carbide semiconductor device according to any one of Appendixes 1 to 10, wherein

the active region includes an SBD region, and

the high point defect density layer is overlapped with at least a part of the SBD region in a plan view.

### Appendix 12

The silicon carbide semiconductor device according to any one of Appendixes 1 to 11, wherein

a junction barrier Schottky diode is provided to the boundary region.

### Appendix 13

The silicon carbide semiconductor device according to any one of Appendixes 1 to 11, wherein

the semiconductor layer further includes a source contact layer of a first conductivity type provided on the well layer, and

the well layer is connected to the source electrode via the source contact layer.

### Appendix 14

The silicon carbide semiconductor device according to any one of Appendixes 1 to11, further comprising

a Schottky electrode provided on the well layer, wherein

the well layer is connected to the source electrode via the Schottky electrode.

### Appendix 15

A power conversion apparatus, comprising:

a conversion circuit including the silicon carbide semiconductor device according to any one of Appendixes 1 to 14, and converting and outputting an electrical power inputted to the conversion circuit;

a drive circuit outputting a drive signal for driving the silicon carbide semiconductor device to the silicon carbide semiconductor device; and

a control circuit outputting a control signal for controlling the drive circuit to the drive circuit.

While the disclosure has been shown and described in detail, the foregoing description is in all aspects illustrative and not restrictive. It is therefore understood that numerous modifications and variations can be devised.

What is claimed is:

1. A silicon carbide semiconductor device, comprising:
a semiconductor layer made of silicon carbide where an active region in which main current flows, an outer surrounding region surrounding the active region, and a boundary region between the active region and the outer surrounding region are defined; and
a source electrode provided to an upper side of the semiconductor layer, wherein
the semiconductor layer includes:
a drift layer of a first conductivity type; and
a well layer of a second conductivity type provided on the drift layer in the boundary region and connected to the source electrode,
the drift layer in the boundary region includes at least one high point defect density layer overlapped with at least a part of the well layer in a plan view and provided below the well layer to be away from the well layer in a cross-sectional view, and
a point defect density of the high point defect density layer is higher than a point defect density of the drift layer other than the high point defect density layer.

2. The silicon carbide semiconductor device according to claim 1, wherein
the active region includes a MOSFET region in which the main current flows and an SBD region in which reflux current flows.

3. The silicon carbide semiconductor device according to claim 1, wherein
the active region includes a MOSFET region in which the main current flows and electrical power is conducted in a reverse direction in a reflux operation.

4. The silicon carbide semiconductor device according to claim 1, wherein
a point defect density of the drift layer in the active region is lower than a point defect density of the drift layer in the boundary region.

5. The silicon carbide semiconductor device according to claim 1, wherein
a point defect density of the drift layer in the outer surrounding region is lower than a point defect density of the drift layer in the boundary region.

6. The silicon carbide semiconductor device according to claim 1, wherein
a gate pad is provided to the outer surrounding region, and
a point defect density of the drift layer below the gate pad is higher than a point defect density of the drift layer in the active region.

7. The silicon carbide semiconductor device according to claim 1, wherein
a distance from the high point defect density layer to the well layer is smaller than a distance from the high point defect density layer to a lower end of the drift layer.

8. The silicon carbide semiconductor device according to claim 1, wherein
a distance from the high point defect density layer to the lower end of the drift layer is smaller than a distance from the high point defect density layer to the well layer.

9. The silicon carbide semiconductor device according to claim 1, wherein
the plurality of high point defect density layers are arranged from the well layer toward the lower end of the drift layer.

10. The silicon carbide semiconductor device according to claim 9, wherein
at least one of the plurality of high point defect density layers is provided across a boundary between the active region and the boundary region.

11. The silicon carbide semiconductor device according to claim 1, wherein
the active region includes an SBD region, and
the high point defect density layer is overlapped with at least a part of the SBD region in a plan view.

12. The silicon carbide semiconductor device according to claim 1, wherein
a junction barrier Schottky diode is provided to the boundary region.

13. The silicon carbide semiconductor device according to claim 1, wherein
the semiconductor layer further includes a source contact layer of a first conductivity type provided on the well layer, and
the well layer is connected to the source electrode via the source contact layer.

14. The silicon carbide semiconductor device according to claim 1, further comprising
a Schottky electrode provided on the well layer, wherein
the well layer is connected to the source electrode via the Schottky electrode.

15. A power conversion apparatus, comprising:
a conversion circuit including the silicon carbide semiconductor device according to claim 1, and converting and outputting an electrical power inputted to the conversion circuit;
a drive circuit outputting a drive signal for driving the silicon carbide semiconductor device to the silicon carbide semiconductor device; and
a control circuit outputting a control signal for controlling the drive circuit to the drive circuit.
